(19) United States
(12) Patent Application Publication
(10) Pub. No.: US 2013/0228664 A1
(43) Pub. Date: Sep. 5, 2013

(54) SUPPORTING APPARATUS FOR COMPUTER ENCLOSURE

(71) Applicant: LI-REN FU, Shenzhen City (CN)

(72) Inventor: LI-REN FU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/434,799

(22) Filed: Mar. 29, 2012

(30) Foreign Application Priority Data
Mar. 1, 2012 (CN) 201210050900.8

(51) Int. Cl. H05K 7/00

(52) U.S. Cl. 248/316.1

(57) ABSTRACT

A supporting apparatus for supporting a computer enclosure with a bottom wall includes an attaching member fixed to the bottom wall, a positioning member fixed to the attaching member, and a supporting member. The supporting member includes a rotating portion rotatably fitted about the attaching member and the positioning member. The rotating portion defines a cutout. A stopping bar protrudes out from the attaching member, and is movable within the cutout and is blocked by each of two ends of the cutout when the supporting member is respectively exposed out of the bottom wall of the computer enclosure to support the computer enclosure and the supporting member is located within the contour of the bottom wall for saving space. A protrusion protrudes from the positioning member. A number of projections protrude from the rotating portion, and are slidably passed through and blocked by the protrusion.

### BACKGROUND

1. Technical Field

The present disclosure relates to supporting apparatus, and particularly to a supporting apparatus for supporting a computer enclosure.

2. Description of Related Art

Personal computers generally includes two types: tower computers and desktop computers. Due to the trend towards miniaturization, a tower computer is made thinner than before. Because of this, the tower computer may be unstable once it has been positioned. It is important to provide stands for supporting the tower computer in a more stable manner.

A conventional stand such as a stand disclosed in U.S. Pat. No. 6,364,278, includes two coupled supporting members. Each supporting member includes a dove-tail shaped protrusion to couple with a recess of the other supporting member. However, a clamping ledge is integrally formed from each supporting member. Therefore, before the stand is assembled to the computer chassis, the stand occupies a rather large space, which is inconvenient to transport or pack.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partially exploded, isometric view of an exemplary embodiment of a supporting apparatus, together with a partial computer enclosure.

FIG. 2 is an inverted view of FIG. 1.

FIG. 3 is an assembled, isometric view of FIG. 1, shows a first state of use.

FIG. 4 is an inverted view of FIG. 3.

FIG. 5 is similar to FIG. 3, but shows a second state of use.

FIG. 6 is an inverted view of FIG. 5.

FIG. 7 is an assembled, isometric view of two of the supporting apparatus and a whole of the computer enclosure of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

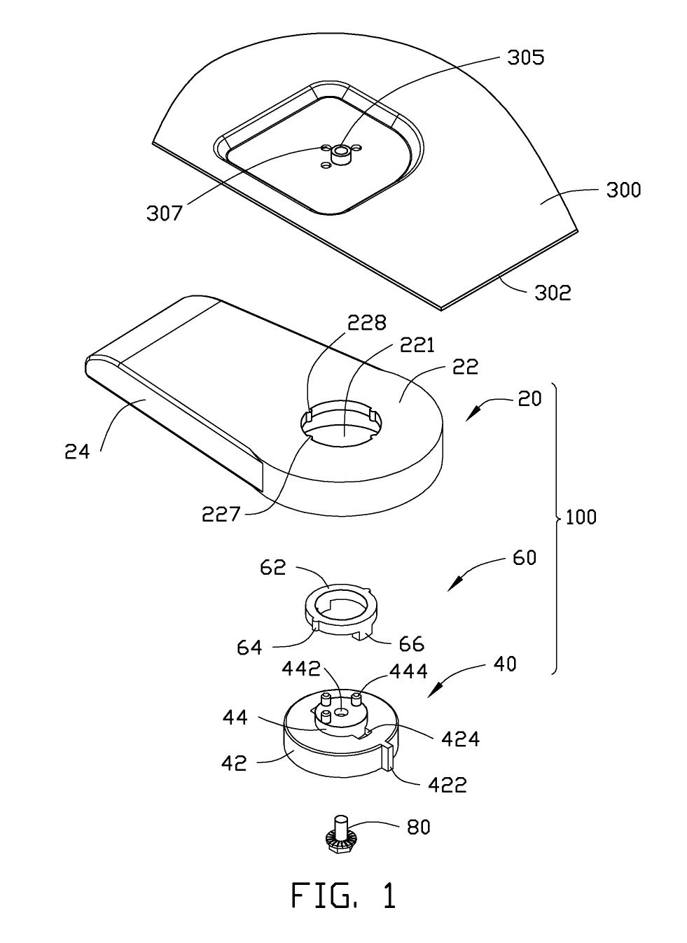

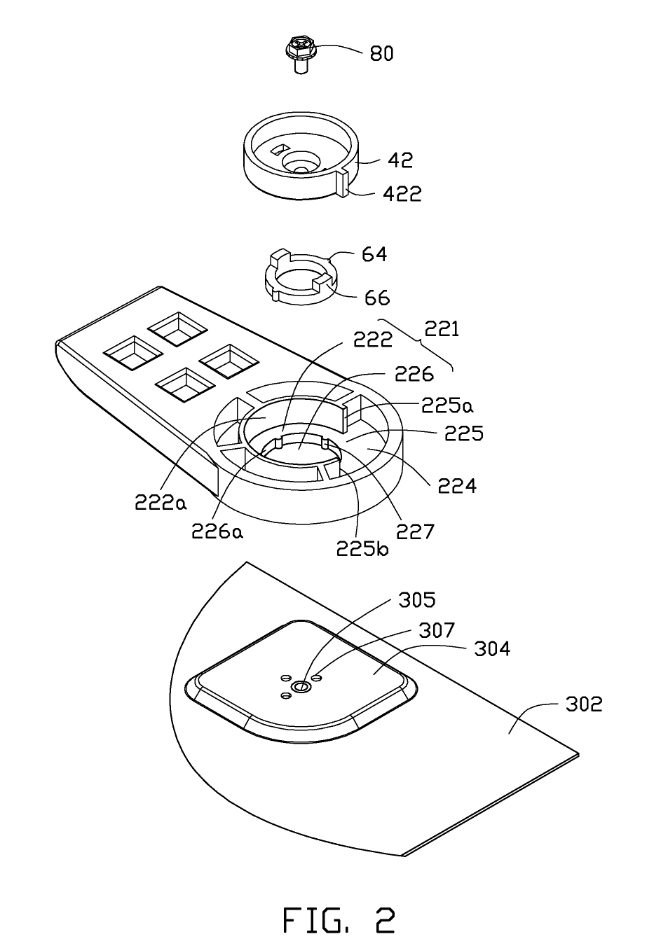

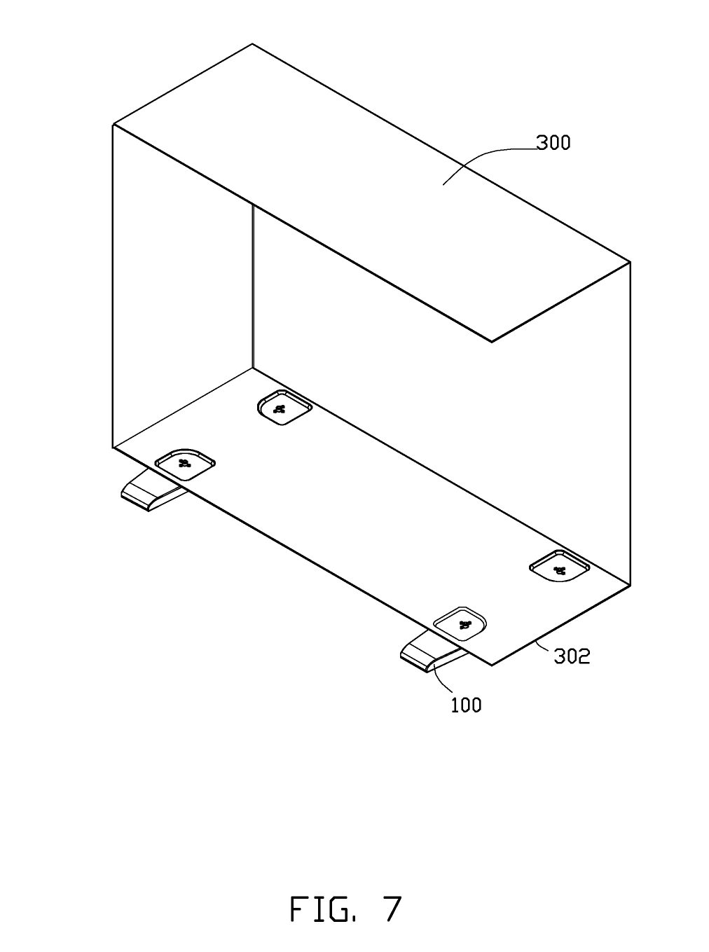

FIGS. 1 and 2, show an exemplary embodiment of a supporting apparatus for supporting a computer enclosure 300 which is wholly shown in FIG. 7. The computer enclosure 300 includes a rectangular bottom wall 302. Four projecting portions 304 protrude out from four corners of the bottom wall 302. A middle of each projecting portion 304 defines a screw hole 305, and a plurality of latching holes 307 surrounding the screw hole 305. The supporting apparatus includes four holders 100. Each holder 100 includes a supporting member 20, an attaching member 40, a positioning member 60, and a screw 80.

The supporting member 20 is substantially rectangular, and includes an arc-shaped rotating portion 22 formed at a first end of the supporting member 20, and a supporting portion 24 formed at a second end of the supporting member 20 opposite to the rotating portion 22. A middle of the rotating portion 22 defines a stepped hole 221, and the stepped hole 221 includes a first hole 226 extending through a top surface of the rotating portion 22, and a second hole 222 extending through a bottom surface of the rotating portion 22 and communicating with the first hole 226. A diameter of the first hole 226 is less than a diameter of the second hole 222.

A cutout 225 is defined in a wall hole 222a of the second hole 222, extending through a quarter of the wall hole 222a of the second hole 222. The cutout 225 includes a first end 225a and a second end 225b opposite to the first end 225a. A bottom surface of the rotating portion 22 defines an arc-shaped avoiding slot 224 communicating with the cutout 225. Two opposite semi-cylindrical first projections 227 protrude out from a wall hole 226a of the first hole 226, extending along a direction perpendicular to the top surface of the rotating portion 22. Two opposite semi-cylindrical second projections 228 protrude out from the wall hole 226a of the first hole 226, extending along the direction perpendicular to the top surface of the rotating portion 22. Two adjacent first and second projections 227 and 228 respectively align with the corresponding first end 225a and second end 225b of the cutout 225.

The attaching member 40 includes a cylindrical main body 42 and a cylindrical raised portion 44 protrudes up from a middle of a top surface of the main body 42. A diameter of the main body 42 is substantially equal to the diameter of the second hole 222. A stopping bar 422 extends out from a circumference of the main body 42. Two opposite latching holes 424 are defined in the top surface of the main body 42, adjacent to the raised portion 44. A middle of a top surface of the raised portion 44 defines a through hole 442 extending through the main body 42. A plurality of pins 444 protrudes up from the top surface of the raised portion 44, surrounding the through hole 442.

The positioning member 60 includes a ring-shaped locating body 62, two opposite resilient protrusions 64 protruding out from a circumference of the locating body 62, and two opposite latching blocks 66 extending down from the locating body 62. A height of the locating body 62 is substantially equal to a depth of the first hole 226.

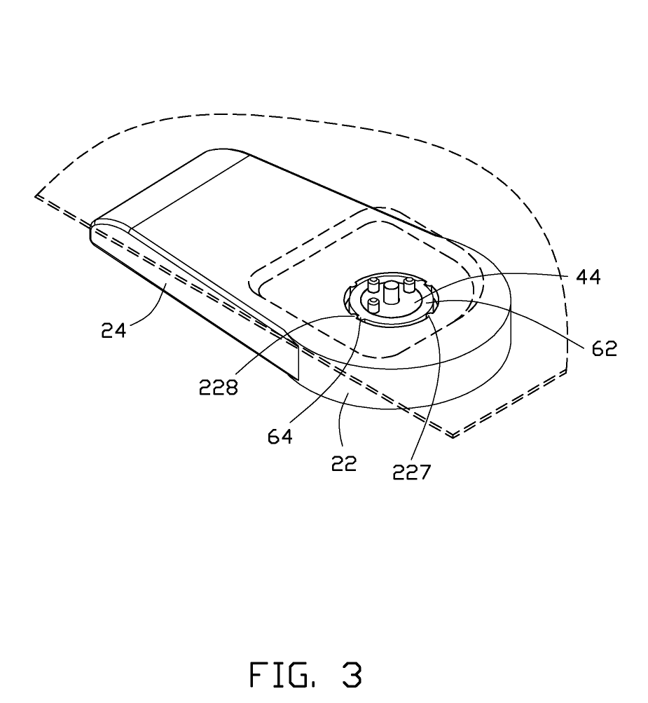

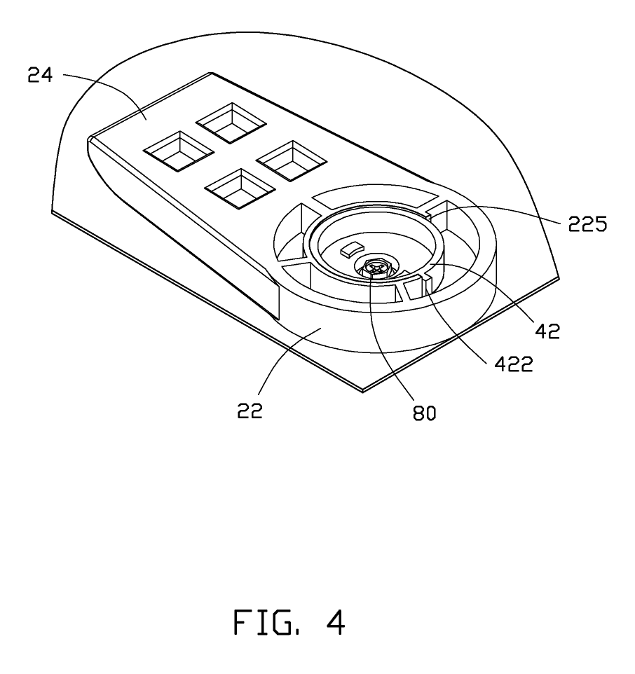

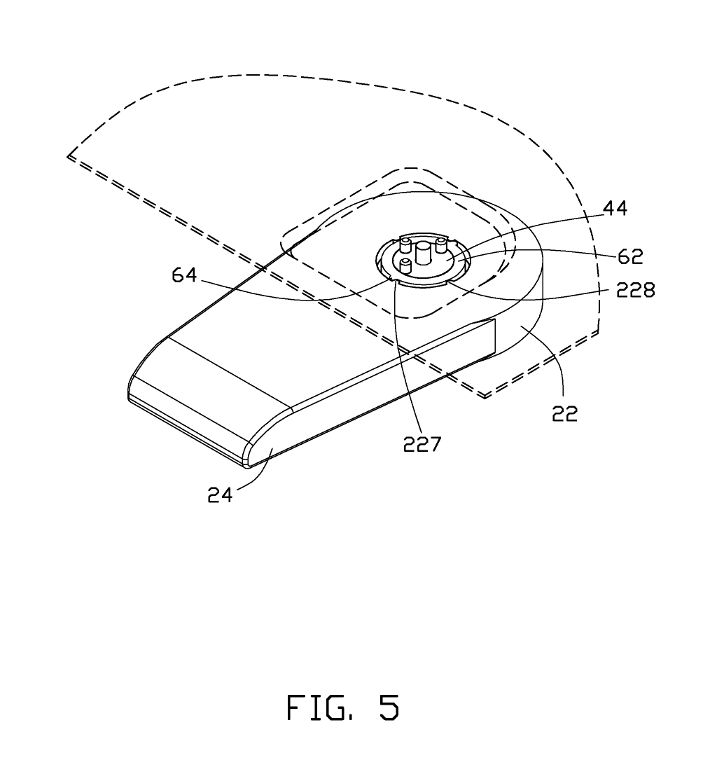

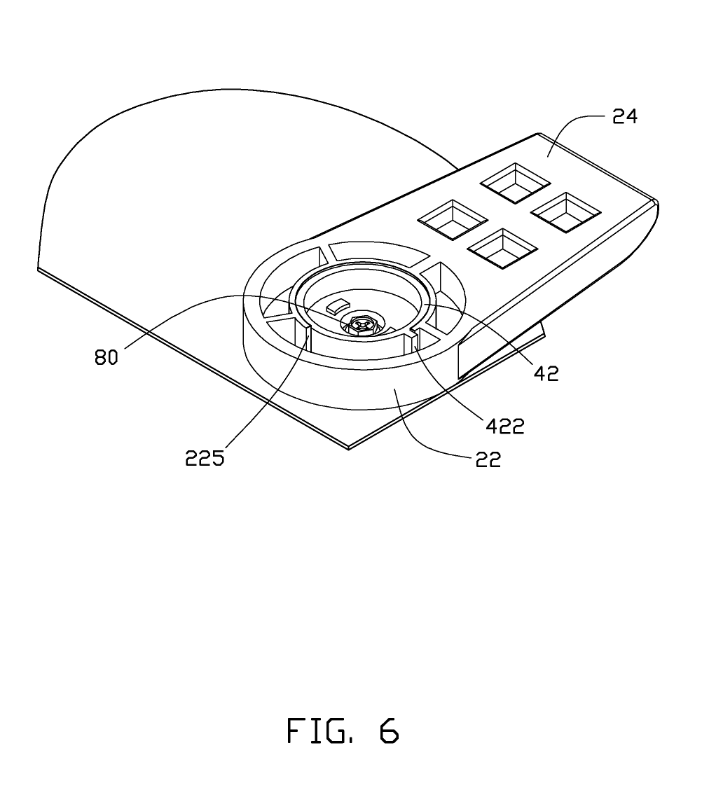

Referring to FIGS. 3-7, in assembly, the latching blocks 66 are inserted into the corresponding latching holes 424, from the top surface of the main body 42. The raised portion 44 is received in the locating body 62. The main body 42 is rotatably received in the second hole 222, and the locating body 62 is rotatably received in the first hole 226, from a bottom of the supporting member 20. The stopping bar 422 is slidably received in the cutout 225 and is blocked between the first end 225a and the second end 225b. The first and second projections 227 and 228 are capable to be slidably passed through the corresponding protrusions 64 or may be blocked by the corresponding protrusions 64. The pins 444 are inserted into the corresponding latching holes 307 from a bottom of the bottom wall 302. The screw 80 extends through the through hole 442, to be screwed into the screw hole 305. The first protrusions 227 are blocked between the protrusions 64, and the stopping bar 422 is blocked by the second end 225b.

When the computer enclosure 300 needs to be supported by the holders 100, each supporting member 20 is rotated out from the bottom wall 302 about the attaching member 40 and the positioning member 60. The first projections 227 are slidably passed through the corresponding protrusions 64, and the stopping bar 422 is rotated from the second end 225b to the first end 225a, until the second projections 228 are passed through and blocked by the corresponding protrusions 64, and the stopping bar 422 is blocked by the first end 225a. At this time, the supporting portion 24 is exposed out of the bottom wall 302 to be substantially perpendicular to the lengthwise direction of the bottom wall 302, and can readily and stably support the computer enclosure 3000.

When the computer enclosure 300 needs to be transported or packed, each supporting member 20 is rotated into a contour of the bottom walls 302. The second projections 228 are slidably passed through the corresponding protrusions 64, and the stopping bar 422 is rotated from the first end 225b to the second end 225a, until the first projections 227 are passed through and blocked by the corresponding protrusions 64, and the stopping bar 422 is blocked by the second end 225a. At this time, each supporting portion 24 is located within the contour of the bottom wall 302 for saving space.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A supporting apparatus for a computer enclosure with a bottom wall, the supporting apparatus comprising:
an attaching member fixed to the bottom wall, and comprising a stopping bar;
a positioning member fixed to the attaching member, and comprising a protrusion; and
a supporting member comprising a rotating portion rotatably fitted about the attaching member and the positioning member, wherein the rotating portion defines a cutout, the stopping bar is slidably received in the cutout, and is selectively blocked by one of two opposite ends of the cutout when the supporting member is respectively exposed out of the bottom wall of the computer enclosure to support the computer enclosure and the supporting member is located within the contour of the bottom wall for saving space, a plurality of projections protrudes from the rotating portion, each projection is slidably passed through blocked by the protrusion.

2. The supporting apparatus of claim 1, wherein the rotating portion defines a stepped hole, the stepped hole comprises a first hole, and a second hole below and communicating with the first hole, a diameter of the first hole is less than a diameter of the second hole, the attaching member further comprises a main body rotatably received in the second hole, the cutout is defined in an wall hole of the second hole, extending through a quarter of the wall hole of the second hole, the positioning member further comprises a ring-shaped locating portion rotatably received in the first hole, the protrusion protrudes out from a circumference of the locating portion, and the projections are protruded out from a wall hole of the first hole.

3. The supporting apparatus of claim 2, wherein the first hole extends through a top surface of the rotating portion, and the second hole extends through a bottom surface of the rotating portion.

4. The supporting apparatus of claim 2, wherein the projections comprises two opposite first projections, and two opposite second projections, two adjacent first and second projections respectively align with the ends of the cutout.

5. The supporting apparatus of claim 2, wherein a raised portion protrudes up from a middle of a top of the main body, the raised portion is received in the locating portion, a pair of latching holes is defined in the top of the main body adjacent to the raised portion, a pair of latching blocks extend down from the locating portion to engage in the corresponding latching holes.

6. The supporting apparatus of claim 5, wherein a projecting portion protrudes down from the bottom wall, the projecting portion defines a screw hole, the raised portion defines a through hole extending through the main body, a screw extends through the through hole of the raised portion from a bottom of the main body, to be screwed into the screw hole.

7. The supporting apparatus of claim 6, wherein a plurality of pins extends up from the raised portion surrounding the through hole, the projecting portion defines a plurality of positioning holes surrounding the screw hole, the pins are inserted into the corresponding positioning holes.
